(19) United States
(12) Patent Application Publication
(10) Pub. No.: US 2024/0038525 A1
(43) Pub. Date: Feb. 1, 2024

(54) A METHOD FOR FABRICATING SEMICONDUCTOR ARTICLES AND SYSTEM THEREOF

(71) Applicant: Inari Technology Sdn Bhd, Bayan Lepas (MY)

(72) Inventor: BOON SENG TEOH, Bayan Lepas (MY)

(73) Assignee: Inari Technology Sdn Bhd, Bayan Lepas (MY)

(21) Appl. No.: 18/268,141

(22) PCT Filed: Dec. 16, 2021
(86) PCT No.: PCT/MY21/50120

§ 371 Date: Jun. 16, 2023

(30) Foreign Application Priority Data
Dec. 17, 2020 (MY) PI 2020006728

(51) Int. Cl. H01L 21/02; H01L 21/683; H01L 21/82; H01L 21/67

(52) U.S. Cl. CPC H01L 21/02013; H01L 21/6836; H01L 21/82; H01L 21/02016; H01L 21/67271; H01L 21/67132; H01L 21/67092

(57) ABSTRACT

The present invention discloses a method for fabricating semiconductor articles comprising the steps of partially cutting a wafer, applying one or more layers of adhesive sheet onto a carrier, transferring the partially cut wafer onto the adhesive sheet on the carrier; grinding a backside of the wafer to a desired thickness to form separated dies, and removing the separated dies from the carrier, wherein the separated dies are removed from the carrier by adhering another layer of adhesive sheet to the backside of the separated dies, in which a heated plate is pressed onto said adhesive sheet thereafter.

### FIELD OF INVENTION

The present invention relates to a method for fabricating semiconductor articles and its system thereof.

### BACKGROUND OF THE INVENTION

In recent years, the spread of integrated circuit packages has been promoted, and further reduction of its thickness thereof is now demanded. Accordingly, it is now required that the thickness of semiconductor chips, which has been about 350 μm, be reduced to about 50-100 μm or less. Such thin semiconductor chips can be obtained by first sticking a surface protective sheet to a circuit surface of a wafer, subsequently grinding the wafer back and thereafter dicing the wafer. When the thickness of the wafer after the grinding is extremely small, chip breakage and chip cracking are likely to occur at the time of the dicing of the wafer.

Many technologies related to fabricating semiconductor articles have been proposed to further improve the system. For example, a United States patent with publication no. U.S. Pat. No. 8,679,895B2 discloses embodiments related to integrated circuit (IC) circuit sensors being fabricated using thin-wafer manufacturing technologies which include processing in which dicing before grinding (DBG) is utilized, which can improve reliability and minimize stress effects on the wafer. While other embodiments utilize face-up mounting, face-down mounting is made possible by through-contacts. Another United States patent with publication no. U.S. Pat. No. 6,558,975B2 discloses a process for producing a semiconductor device comprising the steps of providing a wafer having a surface furnished with semiconductor circuits and a back; forming grooves of a depth smaller than the thickness of the wafer, said grooves extending from the wafer circuit surface; sticking a surface protective sheet onto the wafer circuit surface, grinding the back of the wafer so that the thickness of the wafer is reduced, subsequently reducing in division of the wafer into individual chips with spaces therebetween; sticking a pressure sensitive adhesive sheet onto the ground back of the wafer, exposing the adhesive layer to an energy source; and peeling the surface protective sheet from the wafer circuit surface. A publication by Weng et. al recites a method of stress dicing on semiconductor devices for reduction of defects as well as die strength enhancement, whereby partial stress dicing is performed before grinding of the wafer die. The publication further reports on the elimination of mechanical and absorptive laser singulation related defects such as front side and backside surface ablation, and topside, backside and edge chipping. Besides that, a technology as disclosed by a United States patent with publication no. U.S. Pat. No. 6,337,258B1 recites a method of dividing a wafer by forming grooves in an element formation surface of a wafer along dicing lines or chip dividing lines, whereby the grooves are deeper than a thickness of a finished chip. The method further discloses a holding member being attached on the element formation surface of the wafer and a bottom surface of the wafer is lapped and polished to the thickness of the finished chip, thereby dividing the wafer into chips, before being transferred while being held by porous adsorption.

The aforementioned patent documents describe the many systems and methods for fabricating semiconductor articles, which are key components in the proposed invention. A major drawback arises therefrom as the systems and methods as disclosed in the prior arts lack a means for removing adhesive sheets from the semiconductor wafers without having to peel them from said wafers. Therefore, there exists a need for such a system that is able to perform a dicing before grinding process and also employs a means for eliminating the adhesiveness of the adhesive sheets by simply applying adequate pressure and heat onto said sheets.

### SUMMARY OF INVENTION

It is an object of the present invention to reduce and potentially eliminate risks of backside chipping due to conventional methods of dicing the wafer after backside grinding, whereby the present invention reverses the process by dicing firstly before grinding. It is also an object of the present invention to improve the wafer die strength.

Besides that, it is also an object of the present invention to provide a method of separating wafer dies from a carrier without having to peel of an adhesive sheet that is laminated on one surface of the wafer.

In an aspect of the present invention, there is provided a method for fabricating semiconductor articles comprising the steps of partially cutting a wafer, applying one or more layers of adhesive sheet onto a carrier, transferring the partially cut wafer onto the adhesive sheet on the carrier; grinding a backside of the wafer to a desired thickness to form separated dies, and removing the separated dies from the carrier, wherein the separated dies are removed from the carrier by adhering another layer of adhesive sheet to the backside of the separated dies, in which a heated plate is pressed onto said adhesive sheet thereafter.

Preferably, the layers of adhesive sheet include a thermal tape and an ultraviolet (UV) tape.

Preferably, the additional layer of adhesive sheet is a dicing tape.

Preferably, the carrier is made of silicon and/or glass.

Preferably, the wafer is partially cut up to 20% from total wafer thickness.

Preferably, the heated plate is pressed onto the adhesive sheet and the separated dies for a predetermined period.

In another aspect of the invention, there is provided a system for fabricating semiconductor articles comprising a sawing blade for partially cutting a wafer, an adhesive applying mechanism to apply one or more layers of adhesive sheets onto a carrier (203), a transferring mechanism to transfer the partially cut wafer (200) onto the carrier (203), a back grinding wheel for grinding a backside of the wafer to form separated dies, wherein the separated dies are removed from the carrier by adhering another layer of adhesive sheet to the backside of the separated dies, in which a heated plate is pressed onto said adhesive sheet thereafter.

Preferably, the system further comprises a sorting mechanism for sorting the dies upon inspection.

Preferably, the carrier is made of silicon and/or glass.

Preferably, the adhesive layers include a thermal tape, an ultraviolet (UV) tape, and a dicing tape.

One skilled in the art will readily appreciate that the present invention is well adapted to carry out the objects and obtain the ends and advantages mentioned, as well as those inherent therein. The embodiment described herein is not intended as limitations on the scope of the invention.

### BRIEF DESCRIPTION OF THE DRAWINGS

For the purpose of facilitating an understanding of the invention, there is illustrated in the accompanying drawing the preferred embodiments from an inspection of which when considered in connection with the following description, the invention, its construction and operation and many of its advantages would be readily understood and appreciated.

FIG. 1 is a flow chart illustrating a process of manufacturing a semiconductor wafer.

FIG. 2 is a flow chart illustrating a process of partial cutting and backside grinding a semiconductor wafer.

FIG. 3 is a flow chart illustrating a first technique of applying one or more adhesive sheets to a carrier and front side of the wafer.

FIG. 4 is a flow chart illustrating a first technique of removing the wafer from the carrier.

FIG. 5 is a flow chart illustrating a second technique of applying the adhesive sheet to the carrier and front side of the wafer.

FIG. 6 is a flow chart illustrating a second technique of removing the wafer from the carrier.

### DETAILED DESCRIPTION OF THE INVENTION

Hereinafter, the invention shall be described according to the preferred embodiments of the present invention and by referring to the accompanying description and drawings. However, it is to be understood that limiting the description to the preferred embodiments of the invention is merely to facilitate discussion of the present invention and it is envisioned that those skilled in the art may devise various modifications without departing from the scope of the appended claim.

The invention will now be described in greater detail, by way of example with reference to the drawings.

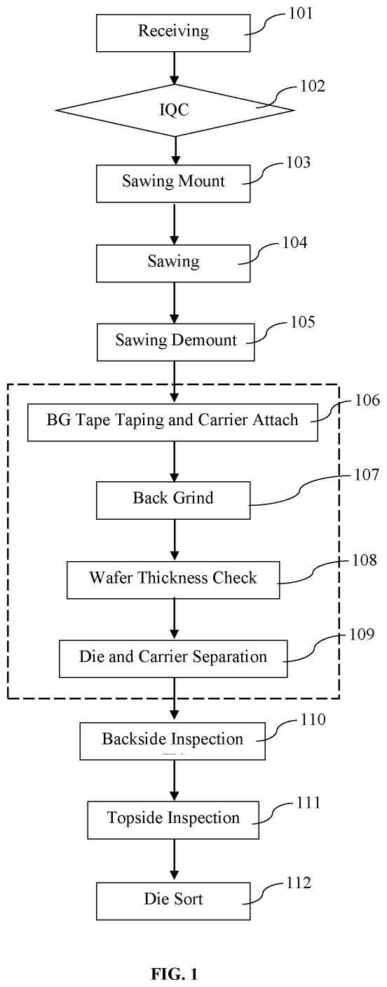

FIG. 1 is a flow chart illustrating a method for fabricating semiconductor articles according to the present invention, the method comprising the steps of firstly receiving a semiconductor article, preferably a semiconductor wafer 200 at Step 101, then inspected through incoming quality control (IQC) at Step 102. IQC is a process of controlling quality of materials and parts for manufacturing a product before production begins. In a preferred embodiment, the present invention employs a method known as “dice before grind,” in which the wafer 200 is cut before it is grinded to form a plurality of separated dies 300. At Step 103, a sawing blade 201 is mounted for a dicing process which cuts the wafer 200 into the plurality of separated dies 300 at Step 104. Preferably, the sawing blade 201 may partially cut a front side of the wafer 200 to a desired depth.

At Step 105, the sawing blade 201 is demounted and replaced with a back grinding wheel 202 for grinding a backside of the wafer 200 at Step 107. Preferably, the back grinding wheel 202 may be a cup wheel which may comprise abrasive grains or abrasive grits, bond material, and pores, and may be manufactured in a variety of grades or structures determined by relative volume percentage of abrasive grains, bond, and porosity. Harder wheels are used in coarse grinding to obtain a longer wheel life. Softer wheels are used in fine grinding to ensure self-dressing ability. In a particular embodiment, the back grinding process is preferred because it is faster and less costly than newer chemical or plasma etching process which have been recently developed. However, some disadvantages may arise such as mechanical stress and heat may be applied during the back grinding process and scratches may also appear. These scratch patterns and depth of the scratches on the surface of the wafer 200 are directly proportional to the size of the grit and the pressure exerted on the wafer 200 during the back grinding process. Further, the depth of the scratches and the backside surface roughness on the semiconductor die 300 have a direct correlation to the strength of the die 300, so it is essential that the finished backside surface of the wafer 200 be as smooth or polished as possible.

At Step 106, one or more layers of adhesive sheets are attached to a carrier 203 by an adhesive applying mechanism, whereby the partially cut wafer 200 will adhere to an adhesive side of the adhesive sheet. In thin semiconductor wafer 200 processes, the wafer 200 is temporarily bonded to a rigid carrier 203 using one or more layers of adhesive sheets upon transferring the partially cut wafer 200 onto the carrier 203 by a transferring mechanism. Preferably, the carrier 203 is made of materials such as by way of example but not limited to, silicon or glass. Glass may be preferred as the carrier 203 due to its thermal and mechanical stability and also chemical resistance. Bonding to and de-bonding from glass carriers 203 can also be monitored since they are transparent. Furthermore, glass carriers 203 can be cleaned and re-used, thus contributing to cost reduction and environmental protection.

In a preferred embodiment, the layer of adhesive sheets may include a thermal tape 204, an ultraviolet (UV) tape 209, a dicing tape 206 or the likes. Thermal tape 204, also known as heat release tape, is used for holding, transfer, carrier masking and protection applications, particularly for semiconductor wafers 200. The thermal tape 204 may be either single-sided, which has a single layer of heat-peelable adhesive, or double-sided, with one side having a heat-peelable adhesive and the other a base surface adhesive. Both types make use of polyester film as a base. The thermal tape 204 may also be used to hold the semiconductor wafer 200 during cutting or to prevent movement of parts.

Dicing tape 206 is a backing tape used during wafer 200 dicing, the cutting apart of pieces of semiconductor material following wafer 200 microfabrication. The dicing tape 207 holds the pieces of semiconductor, known as die 300, together during the cutting process, mounting them to a thin metal frame. The dies 300 are removed from the dicing tape 206 later on in the electronics manufacturing process. Further, dicing tape 206 may be made of polyvinyl chloride (PVC), polyolefin, or polyethylene backing material with an adhesive to hold the die in place. In some cases, dicing tape 206 will have a release liner that will be removed prior to mounting the dicing tape 206 to the backside of the wafer 200.

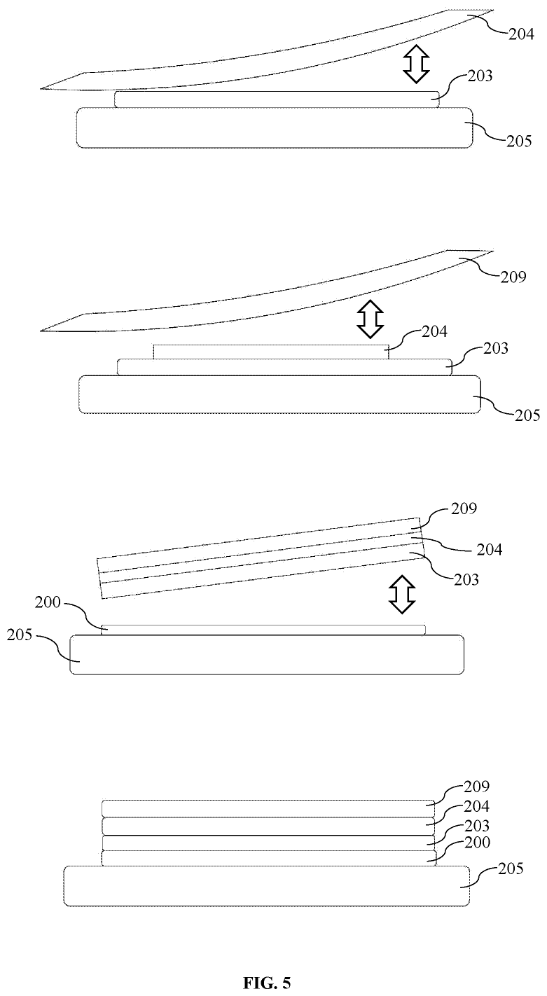

Similar to the thermal tape 204, the UV tape 210 is preferably double-sided, with the other adhesive side to be attached to the front side of the wafer 200 to form another assembly comprising the wafer 200, the thermal tape 204, and the UV tape 210, such as illustrated in FIG. 5. The UV tape 210 is one of many types of dicing tapes 206, in which its adhesive bond is broken by exposure to UV light after dicing, allowing the adhesive to be stronger during cutting while still allowing clean and easy removal. It is suitable to protect surfaces of the wafer 200 during the back grinding process, and to hold the wafer 200 with a ring frame 208 during the dicing process. Alternatively, the UV tape 209 may also be applicable for various work pieces such as ceramics, glass, sapphire and so on.

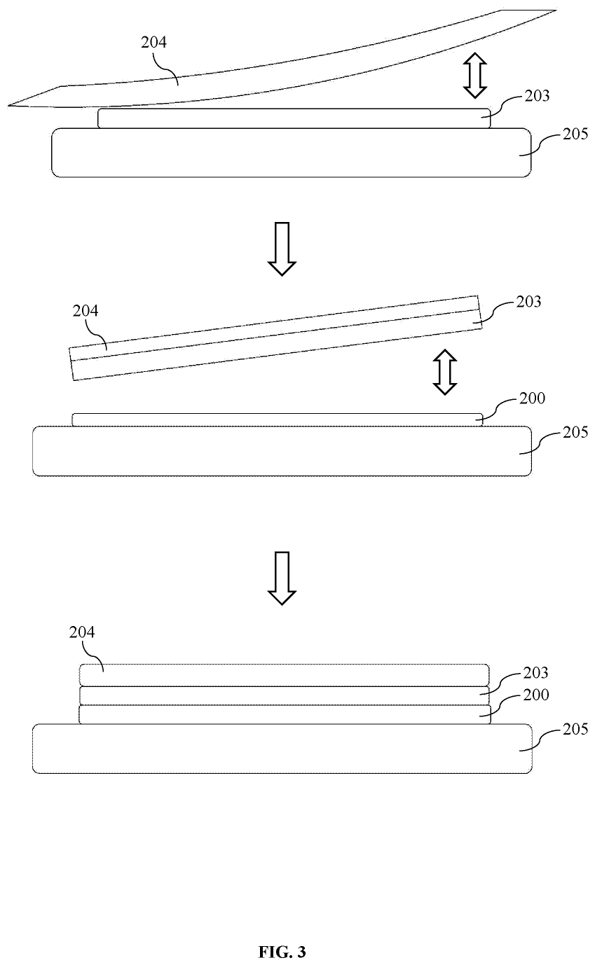

In a preferred embodiment, the back grinding wheel 202 grinds the wafer 200 from its backside to a desired thickness, ranging between 0.850 mm to 0.175 mm for example, such as illustrated in Step 107. At Step 108, the thickness of the grinded wafer 200 or separated dies 300 are checked before the separated dies proceed to be removed from the carrier at Step 109, which will be discussed further herein with reference to FIG. 3 to FIG. 6. Steps 110 to 112 illustrates the steps of inspecting the backside and topside of the separated dies using an inspection device before they are sorted out for their respective applications by a sorting mechanism.

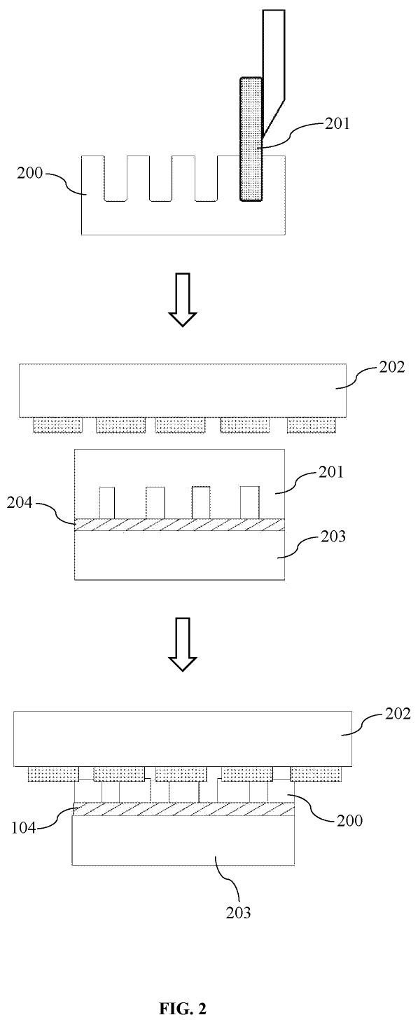

FIG. 2 is a flowchart illustrating a process of dicing before back grinding of the wafer 200. Firstly, the wafer 200 is partially cut during the dicing process, in which the sawing blade 201 cuts through the front side of the wafer 200 to about 20% of the wafer 200 total thickness. Upon cutting a predetermined number of cuts on the wafer 200, preferably transversely across the wafer 200 in two directions perpendicular to each other, so that the cuts form squares on the wafer 200. Further, the wafer 200 is then adhered to the thermal tape 204 which is attached to the carrier 203 with the front side adhered to one adhesive portion of the thermal tape 204. The thermal tape 204 will help to prevent the wafer from moving around during the back grinding process. The back grinding wheel 202 will then be used to grind the backside of the wafer 200 to a desired thickness as mentioned above.

FIG. 3 to FIG. 6 are flowcharts illustrating two techniques for applying one or more adhesive sheets to the semiconductor wafer 200 and carrier 203. In a preferred embodiment, this technique is applied, preferably after the wafer 200 is partially cut and before it is grinded. Referring to FIG. 3, the first technique employs laminating or applying the thermal tape 204 to the carrier 203 which is placed on a chuck table 205. Once the thermal tape 204 is applied onto the carrier 203, the wafer 200 is placed on the chuck table 205 with its front side facing upwards from the chuck table 205, in which the front side of the wafer 200 is then adhered to the other adhesive side of the thermal tape 204 such as shown in FIG. 3, forming an assembly comprising of the wafer 200, thermal tape 204, and carrier 203. The assembly is then transferred for the wafer 200 to be grinded, wherein the assembly is flipped over to have the carrier 203 away from and the back side of the wafer 200 exposed to the back grinding wheel 202.

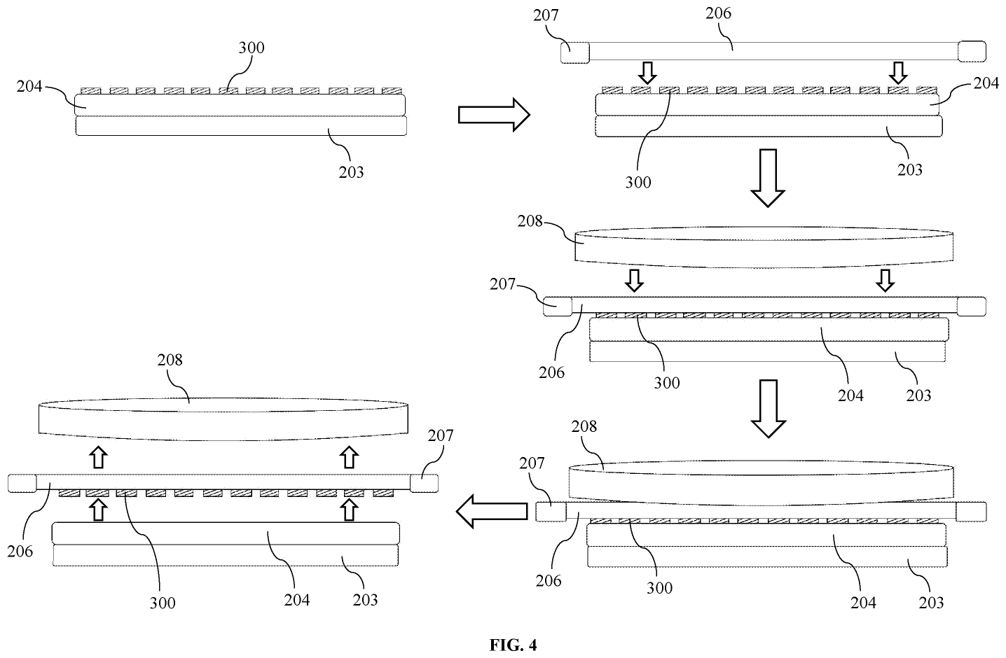

FIG. 4 illustrates the steps for removing the separated dies 300 from the thermal tape 204 and the carrier 203. Dicing tape 206 is attached to a metal frame ring 207 also known as a wafer ring, which is then placed on the backside of the separated dies 300 that have been grinded. Once attached, a heated plate 208 is then pressed gently onto the dicing tape 204 to apply adequate pressure onto the separated dies 300 for a predetermined amount of time, for example 30 seconds or less. The heat from the heated plate 208 will weaken the adhesiveness of the thermal tape 204 on the separated dies 300 while maintaining the adhesiveness of the dicing tape 206, allowing for the separated dies to be adhered to the dicing tape 206 instead and removed from the thermal tape 204 when the dicing tape 206 and the heated plate 208 are lifted up. Subsequently, the separated dies 300 attached to the dicing tape 206 and metal frame ring 207 will be brought to a next station for subsequent processing and/or polishing.

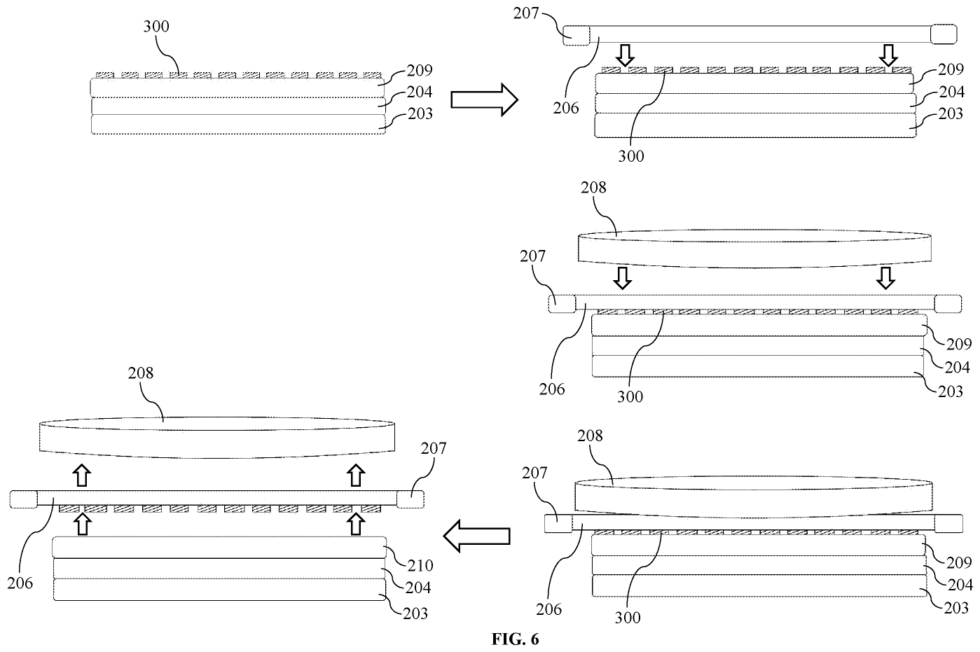

In a further embodiment, a second technique as illustrated in FIG. 5 employs laminating the thermal tape 204 onto the carrier 203 similarly to the first technique. A next layer of adhesive, in the form of the ultraviolet (UV) tape 209, is applied on top of the thermal tape 204. FIG. 6 then illustrates the process of removing the separated dies 300 from the UV tape 209, similarly to the first technique, whereby the dicing tape 206 is applied onto the separated dies 304 and the heated plate 208 is then pressed on the dicing tape 206 to remove the adhesive of the UV tape 209. Alternatively, an additional step of UV irradiation onto the UV tape 209 alongside the heated plate 208 may be employed to enhance the removal of the separated dies from the UV tape 209.

The present disclosure includes as contained in the appended claims, as well as that of the foregoing description. Although this invention has been described in its preferred form with a degree of particularly, it is understood that the present disclosure of the preferred form has been made only by way of example and that numerous changes in the details of construction and the combination and arrangements of parts may be resorted to without departing from the scope of the invention.

1.-10. (canceled)

11. A method for fabricating semiconductor articles, comprising the steps of:
partially cutting a wafer;
applying one or more layers of adhesive sheets onto a carrier that is transparent and rigid;
transferring the partially cut wafer onto the adhesive sheet on the carrier;
grinding a backside of the wafer to a desired thickness to form separated dies; and
transferring the separated dies from the adhesive sheet of the carrier to an additional layer of adhesive sheet of a frame ring using a heated plate that has the additional layer of adhesive sheet adhere to the backside of the separated dies;
wherein the carrier supports a pressure exerted by the heated plate during the transfer of the separated dies and provides monitoring of a bonding and de-bonding of the separated dies between adhesive sheets during their transfer.

12. The method according to claim 11, wherein the layers of adhesive sheet of the carrier include either a thermal tape or a combination of the thermal tape and an ultraviolet (UV) tape.

13. The method according to claim 11, wherein the additional layer of adhesive sheet of the frame ring is a dicing tape.

14. The method according to claim 11, wherein the wafer is partially cut up to 20% from total wafer thickness.

15. The method according to claim 11, wherein the heated plate is pressed against the additional adhesive sheet of the frame ring and the backside of the separated dies.

16. A system for fabricating semiconductor articles, comprising:
a sawing blade for partially cutting a wafer;
an adhesive applying mechanism to apply one or more layers of adhesive sheets onto a carrier that is transparent and rigid;
a transferring mechanism to the partially cut wafer onto the adhesive sheet on the carrier;
a back grinding wheel for grinding a backside of the wafer to form separated dies;
a frame ring with an additional layer of adhesive sheet; and
a heated plate that transfers the separated dies from the adhesive sheets of the carrier to the additional layer of adhesive sheet of the frame ring by having the additional layer of adhesive sheet adhere to the backside of the separated dies;
wherein the carrier supports a pressure exerted by the heated plate during the transfer of the separated dies and provides monitoring of a bonding and de-bonding of the separated dies between adhesive sheets during their transfer.

17. The system according to claim 16, further comprising a sorting mechanism for sorting the dies upon inspection.

18. The system according to claim 16, wherein the layers of adhesive sheet of the carrier include either a thermal tape or a combination of the thermal tape and an ultraviolet (UV) tape.

19. The system according to claim 16, wherein the additional layer of adhesive sheet of the frame ring is a dicing tape.
